(19) United States
(12) Patent Application Publication
(10) Pub. No.: US 2025/0158636 A1
(43) Pub. Date: May 15, 2025

(54) DELTA-SIGMA MODULATION APPARATUS AND DELTA-SIGMA MODULATION METHOD

(71) Applicant: NEC Corporation, Tokyo (JP)

(72) Inventors: Daisaku OGASAHARA, Tokyo (JP); Masaaki TANIO, Tokyo (JP)

(73) Assignee: NEC Corporation, Tokyo (JP)

(21) Appl. No.: 18/934,345

(22) Filed: Nov. 1, 2024

(30) Foreign Application Priority Data
Nov. 13, 2023 (JP) 2023-192758

(51) Int. Cl. H03M 3/00

(52) U.S. Cl. CPC H03M 3/50; H03M 3/37; H03M 3/484

(57) ABSTRACT

A delta-sigma modulation apparatus divides an input signal into a plurality of signal blocks, inputs the plurality of signal blocks to a plurality of delta-sigma modulation circuits, and performs combining processing for combining a plurality of output signals from the plurality of delta-sigma modulation circuits.

### CROSS-REFERENCES TO RELATED APPLICATION

The present application claims priority to Japanese patent application No. JP 2023-192758 filed on Nov. 13, 2023, the content of which is hereby incorporated by reference in its entirety.

### BACKGROUND

### Technical Field

The present disclosure relates to a delta-sigma modulation apparatus and a delta-sigma modulation method.

### Background Art

In a field of radio communication, to address increases in traffic, a technology for implementing high-speed communication has been developed.

Usually, to implement high-speed communication, a radio communication apparatus needs to include a high-speed and high-accuracy digital-to-analog converter (DAC). However, the price and power consumption of such a DAC are generally high, and thus there is an issue in that manufacturing costs and power consumption of the radio communication apparatus including the DAC are generally high.

In order to solve the issue described above, a delta-sigma modulation apparatus may be used. The delta-sigma modulation apparatus converts a multi-bit-width digital signal being an input signal to a 1-bit sequence, and outputs the bit sequence as an output signal. The output signal is caused to pass through a bandpass filter having the same passband as a signal band of the input signal. Consequently, an analog signal substantially equivalent to the input signal can be obtained.

The use of the delta-sigma modulation apparatus obviates the need for the DAC, and thus manufacturing costs and power consumption of the radio communication apparatus can be reduced.
[PTL 1] JP 2005-6273 A
[PTL 2] JP 7072734 B

### SUMMARY

For example, when a high-speed digital signal having a sampling frequency exceeding 1G sample/second is processed, it is difficult to process such a digital signal with only one delta-sigma modulation circuit. PTL 1 discloses a plurality of delta-sigma modulation circuits arranged in parallel. According to the configuration, a high-speed digital signal can be processed.

On the other hand, there is an issue in that a calculation error occurs near a boundary of signal blocks of output signals in the plurality of delta-sigma modulation circuits arranged in parallel. PTL 2 discloses a configuration of reducing the calculation error. However, the configuration disclosed in PTL 2 has a plurality of conditional branches, and thus processing is complex. The configuration disclosed in PTL 2 is not suited for the plurality of delta-sigma modulation circuits arranged in parallel that are required to process a high-speed digital signal.

The present disclosure provides a technology enabling reduction of a calculation error with a simpler configuration than that in the related art (for example, PTL 2).

In one or more example embodiments, a delta-sigma modulation apparatus is provided. The delta-sigma modulation apparatus includes one or more memories storing instructions, and one or more processors configured to execute the instructions to divide an input signal into a plurality of signal blocks; implement a parallel circuit including two or more filter circuits arranged in parallel and configured to perform delta-sigma modulation processing on the plurality of signal blocks to output a plurality of output signals corresponding to the plurality of signal blocks, each of the two or more filter circuits including two or more delta-sigma modulation circuits including different initial values; and perform combining processing for combining the plurality of output signals. The two or more delta-sigma modulation circuits in each of the two or more filter circuits are configured to perform the delta-sigma modulation processing on a same signal block to output one of the plurality of output signals and output an output selection signal for combining the plurality of output signals. The one or more processors are further configured to execute the instructions to perform the combining processing using the initial values and the output selection signal from one of the two or more delta-sigma modulation circuits that processes a preceding signal block among the plurality of signal blocks.

In one or more example embodiments, a delta-sigma modulation method in provided. The delta-sigma modulation method includes dividing an input signal into a plurality of signal blocks; inputting the plurality of signal blocks to two or more filter circuits to output a plurality of output signals corresponding to the plurality of signal blocks, the two or more filter circuits being arranged in parallel, each of the two or more filter circuits including two or more delta-sigma modulation circuits including different initial values; and performing combining processing for combining the plurality of output signals. The delta-sigma modulation method further includes performing delta-sigma modulation processing on a same signal block to output one of the plurality of output signals and an output selection signal for combining the plurality of output signals, using the two or more delta-sigma modulation circuits in each of the two or more filter circuits; and performing the combining processing using the initial values and the output selection signal from one of the two or more delta-sigma modulation circuits that processes a preceding signal block among the plurality of signal blocks.

According to the configuration, a calculation error can be reduced with a simpler configuration than that in the related art. Issues, configurations, and effects other than above will be clarified by the following description of example embodiments.

### BRIEF DESCRIPTION OF THE DRAWINGS

FIG. 1 is a diagram illustrating an example of a configuration of a delta-sigma modulation apparatus 10;

FIG. 2 is a diagram illustrating an example of a configuration of a delta-sigma modulation circuit 200;

FIG. 3 is a diagram illustrating an example of a configuration of a delta-sigma modulation circuit 300;

FIG. 4 is a diagram illustrating an example of a configuration of an error feedback delta-sigma modulation circuit 400;

FIG. 5 is a diagram illustrating an example of a relationship between an input signal to a parallel circuit section 120 and an output signal from a combining section 130;

FIG. 6 is a table illustrating a circuit state of a delta-sigma modulation circuit 121-1 in a process of processing signal block #J;

FIG. 7 is a table illustrating a circuit state of a delta-sigma modulation circuit 122-1 in a process of processing signal block #J+1;

FIG. 8 is a table illustrating the circuit state of the delta-sigma modulation circuit 122-1 in a process of processing signal block #J+1;

FIG. 9 is a graph illustrating an example of a calculation error due to discontinuity calculated by means of a simulation;

FIG. 10 is a diagram illustrating an example of a configuration of a delta-sigma modulation apparatus 1000;

FIG. 11 is a diagram illustrating an example of a configuration of an error feedback delta-sigma modulation circuit 1100;

FIG. 12 is a table illustrating a circuit state of a delta-sigma modulation circuit 121-n in a process of processing signal block #J;

FIG. 13 is a table illustrating a circuit state of a delta-sigma modulation circuit 122-n in a process of processing signal block #J+1;

FIG. 14 is a diagram illustrating an example of a configuration of a delta-sigma modulation apparatus 1400;

FIG. 15 is a table illustrating the circuit state of the delta-sigma modulation circuit 121-n in a process of processing signal block #J;

FIG. 16 is a table illustrating the circuit state of the delta-sigma modulation circuit 122-n in a process of processing signal block #J+1;

FIG. 17 is a table illustrating the circuit state of the delta-sigma modulation circuit 121-n in a process of processing signal block #J;

FIG. 18 is a table illustrating the circuit state of the delta-sigma modulation circuit 122-n in a process of processing signal block #J+1;

FIG. 19 is a diagram illustrating an example of a configuration of an error feedback delta-sigma modulation circuit 1900;

FIG. 20 is a diagram illustrating an example of a configuration of a delta-sigma modulation apparatus 2000;

FIG. 21 is a flowchart illustrating a flow of processing of the delta-sigma modulation apparatus 2000; and

FIG. 22 is a diagram illustrating an example of an information processing apparatus 2200 for implementing the delta-sigma modulation apparatus.

### DESCRIPTION OF THE EXAMPLE EMBODIMENTS

Hereinafter, one or more example embodiments will be described with reference to the accompanying drawings. Note that each drawing is associated with the one or more example embodiments in the present disclosure. In the Specification and drawings, elements to which a similar description is applicable are denoted by the same reference sign, and overlapping descriptions may hence be omitted.

Descriptions will be given in the following order.
1. Example Embodiments
   1-1. Overview of Example Embodiments
   1-2. Details of Example Embodiments
   1-3. Configuration of Hardware
2. Other Example Embodiments

### 1. EXAMPLE EMBODIMENTS

An overview of the one or more example embodiments to be described below will be described.

### 1-1. Overview of Example Embodiments

For example, a case is assumed in which a high-speed digital signal having a sampling frequency exceeding 1G sample/second is processed. A drive frequency of a hardware circuit, such as a field programmable gate array (FPGA) or an application specific integrated circuit (ASIC), is lower than a sampling frequency of an input signal, and thus it is difficult to process the input signal with only one delta-sigma modulation circuit.

In order to solve the issue, a delta-sigma modulation apparatus including a plurality of delta-sigma modulation circuits may be used. In the configuration, a plurality of delta-sigma modulation circuits are arranged in parallel. The delta-sigma modulation apparatus divides an input signal into a plurality of signal blocks each having a predetermined data length, and inputs the plurality of signal blocks to a plurality of delta-sigma modulation circuits. According to the configuration, a high-speed digital signal can be processed.

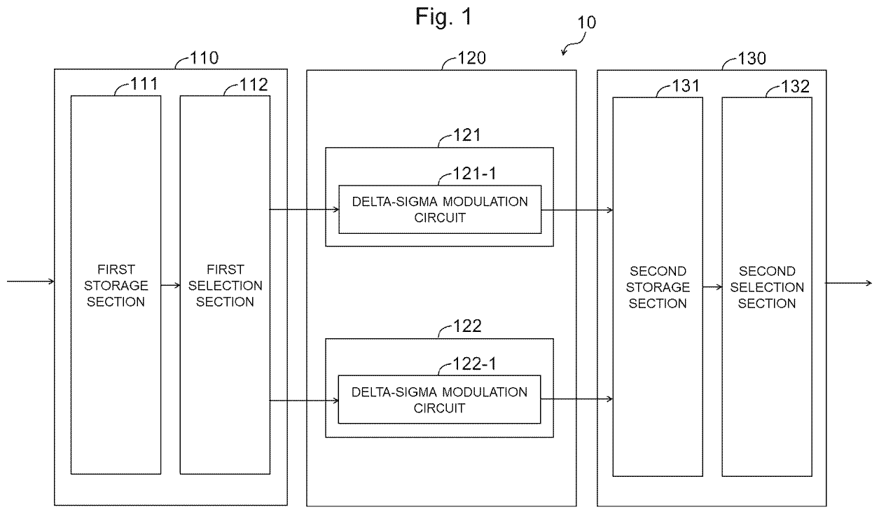

FIG. 1 is a diagram illustrating an example of a configuration of a delta-sigma modulation apparatus 10. The delta-sigma modulation apparatus 10 includes a dividing section 110, a parallel circuit section 120, and a combining section 130.

The dividing section 110 includes a first storage section 111 and a first selection section 112. The first storage section 111 stores multi-bit-width digital data being input signals. The first selection section 112 receives the digital data from the first storage section 111. The first selection section 112 divides the digital data into a plurality of signal blocks. The first selection section 112 inputs the plurality of signal blocks to the parallel circuit section 120.

The parallel circuit section 120 includes a plurality of filter circuits 121 and 122. The plurality of filter circuits 121 and 122 are arranged in parallel. Note that, in the present example, for the sake of simplicity of description, the number of filter circuits is 2; however, the example embodiments are not restricted to this configuration. Three or more filter circuits may be arranged in parallel.

The first selection section 112 inputs the plurality of signal blocks to the plurality of filter circuits 121 and 122. The signal blocks input to the filter circuit 121 and the signal blocks input to the filter circuit 122 are different from each other (i.e., do not overlap each other).

The filter circuit 121 includes a delta-sigma modulation circuit 121-1. The delta-sigma modulation circuit 121-1 performs delta-sigma modulation processing on a plurality of data segments included in the signal block. As will be described below, the signal block has a predetermined data length. The delta-sigma modulation circuit 121-1 sequentially performs processing on first data to last data included in the signal block. The delta-sigma modulation circuit 121-1 outputs an output signal (1-bit sequence) to the combining section 130.

Similarly, the filter circuit 122 includes a delta-sigma modulation circuit 122-1. The delta-sigma modulation circuit 122-1 performs delta-sigma modulation processing on a plurality of data segments included in the signal block. The delta-sigma modulation circuit 122-1 sequentially performs processing on first data to last data included in the signal block. The delta-sigma modulation circuit 122-1 outputs an output signal (1-bit sequence) to the combining section 130.

The combining section 130 includes a second storage section 131 and a second selection section 132. The second storage section 131 stores the output signal from the delta-sigma modulation circuit 121-1 and the output signal from the delta-sigma modulation circuit 122-1. The second selection section 132 outputs a plurality of output signals stored in the second storage section 131. The second selection section 132 sequentially outputs processed results (1-bit sequence) from ones of the signal block input to the second storage section 131 at earliest time.

For the sake of description, the data of the signal block input to the delta-sigma modulation circuits is hereinafter referred to as “input data”. The processed results (i.e., the output signal) output from the delta-sigma modulation circuits are referred to as “output data”.

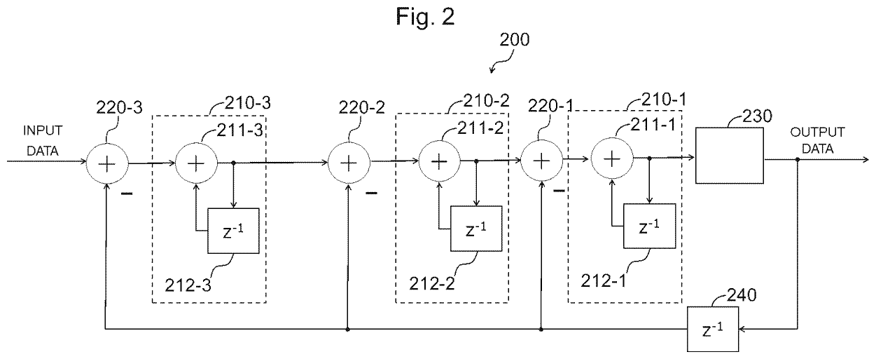

FIG. 2 is a diagram illustrating an example of a configuration of a delta-sigma modulation circuit 200. The delta-sigma modulation circuit 200 is an N-th-order delta-sigma modulation circuit. N represents the order of the delta-sigma modulation circuit. As the value of N is greater, performance of noise shaping as characteristics of the delta-sigma modulation circuit is more satisfactory. Note that, in the present example, for the sake of simplicity of description, N=3; however, the example embodiments are not restricted to this configuration. A delta-sigma modulation circuit of fourth order or higher may be used.

The delta-sigma modulation circuit 200 includes integrators 210-1, 210-2, and 210-3, adders-subtractors 220-1, 220-2, and 220-3, a quantization section 230, and a delay device 240.

The integrators 210-1, 210-2, and 210-3 are connected in series. The adders-subtractors 220-1, 220-2, and 220-3 are respectively arranged on the input side of the integrators 210-1, 210-2, and 210-3.

An output signal of the integrator 210-1 is input to the quantization section 230. The quantization section 230 quantizes the output signal of the integrator 210-1 to output a 1-bit sequence as output data. The output data is stored in the delay device 240. Subsequently, the output data is fed back to the adders-subtractors 220-1, 220-2, and 220-3.

Thus, the adder-subtractor 220-3 outputs a signal calculated from input data and the output data to the integrator 210-3 as the output signal. The integrator 210-3 processes the output signal of the adder-subtractor 220-3 to output the output signal to the adder-subtractor 220-2. The adder-subtractor 220-2 outputs a signal calculated from the output signal of the integrator 210-3 and the output data to the integrator 210-2 as an output signal. The integrator 210-2 processes the output signal of the adder-subtractor 220-2 to output the output signal to the adder-subtractor 220-1. The adder-subtractor 220-1 outputs a signal calculated from the output signal of the integrator 210-2 and the output data to the integrator 210-1 as the output signal. The integrator 210-1 processes the output signal of the adder-subtractor 220-1 to output the output signal to the quantization section 230.

The configurations of the integrators 210-1, 210-2, and 210-3 are the same. Here, the integrator 210-1 will be described, and description of other integrators 210-2 and 210-3 will be omitted. The integrator 210-1 includes an adder-subtractor 211-1 and a delay device 212-1. An output signal of the adder-subtractor 211-1 is fed back to the adder-subtractor 211-1 via the delay device 212-1.

As illustrated in FIG. 2, the delta-sigma modulation circuit 200 is a type of infinite impulse response (IIR) filter. The delta-sigma modulation circuit 200 includes the quantization section 230 arranged on a feedback path, and outputs a 1-bit sequence as output data.

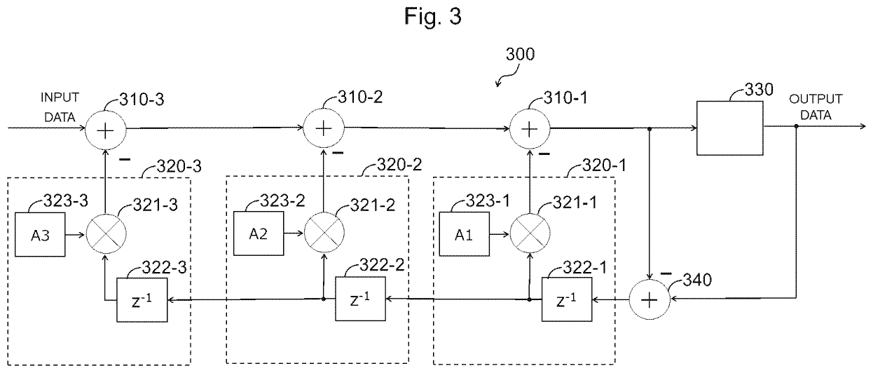

FIG. 3 is a diagram illustrating an example of a configuration of a delta-sigma modulation circuit 300. The delta-sigma modulation circuit 300 is an example alteration of the configuration of the delta-sigma modulation circuit 200 of FIG. 2. The delta-sigma modulation circuit 300 is also referred to as an “error feedback N-th-order delta-sigma modulation circuit”. Note that, in the present example as well, for the sake of simplicity of description, N=3; however, the example embodiments are not restricted to this configuration. A delta-sigma modulation circuit of fourth order or higher may be used.

The delta-sigma modulation circuit 300 includes adders-subtractors 310-1, 310-2, and 310-3, feedback amount calculation sections 320-1, 320-2, and 320-3, a quantization section 330, and an adder-subtractor 340.

The adder-subtractor 310-3 outputs a signal calculated from input data and an output signal of the feedback amount calculation section 320-3 to the adder-subtractor 310-2 as an output signal. The adder-subtractor 310-2 outputs a signal calculated from the output signal of the adder-subtractor 310-3 and the output signal of the feedback amount calculation section 320-2 to the adder-subtractor 310-1 as an output signal. The adder-subtractor 310-1 outputs a signal calculated from the output signal of the adder-subtractor 310-2 and the output signal of the feedback amount calculation section 320-1 to the quantization section 330 as an output signal.

The quantization section 330 quantizes the output signal of the adder-subtractor 310-1 to output a 1-bit sequence as output data. The adder-subtractor 340 outputs a signal calculated from the output signal of the adder-subtractor 310-1 and the output data to the feedback amount calculation section 320-1 as an output signal. The output signal of the adder-subtractor 340 is also fed back to the feedback amount calculation section 320-2 and the feedback amount calculation section 320-3.

The configurations of the feedback amount calculation sections 320-1, 320-2, and 320-3 are the same. Here, the feedback amount calculation section 320-1 will be described. The feedback amount calculation section 320-1 includes a multiplier 321-1, a delay device 322-1, and a coefficient storage 323-1. The coefficient storage 323-1 stores a feedback gain A1. The output signal of the adder-subtractor 340 is input to the multiplier 321-1 via the delay device 322-1. The multiplier 321-1 multiplies the output signal of the adder-subtractor 340 and the feedback gain A1 to output a multiplied result to the adder-subtractor 310-1.

Note that other feedback amount calculation sections 320-2 and 320-3 are different from the feedback amount calculation section 320-1 in the following. A coefficient storage 323-2 of the feedback amount calculation section 320-2 stores a feedback gain A2. A coefficient storage 323-3 of the feedback amount calculation section 320-3 stores a feedback gain A3.

As described above, the delta-sigma modulation circuit 300 has a configuration of feeding the output signal of the adder-subtractor 340 (i.e., an error signal between the input signal and the output signal of the quantization section 330) back to the adders-subtractors 310-1, 310-2, and 310-3 via the feedback amount calculation sections 320-1, 320-2, and 320-3.

When all of the feedback gains A1, A2, and A3 are 1, the configuration of the delta-sigma modulation circuit 200 of FIG. 2 and the configuration of the delta-sigma modulation circuit 300 of FIG. 3 are equivalent. On the other hand, the delta-sigma modulation circuit 300 can be implemented with a smaller number of components (for example, the adders-subtractors and the delay device) than the delta-sigma modulation circuit 200. Considering that a circuit scale of the delta-sigma modulation circuit 300 can be made smaller than the delta-sigma modulation circuit 200, the delta-sigma modulation circuit 300 has an advantage over the delta-sigma modulation circuit 200.

Furthermore, in the delta-sigma modulation circuit 300, the feedback amount calculation section 320-1 multiplies the error signal (i.e., the output signal of the adder-subtractor 340) by the feedback gain A1. The feedback amount calculation sections 320-2 and 320-3 can also perform similar processing. The delta-sigma modulation circuit 300 also has an advantage in that characteristics of noise shaping can be controlled by adjusting the feedback gains A1, A2, and A3.

The following will describe one or more example embodiments using the error feedback N-th-order delta-sigma modulation circuit. Note that, for the sake of simplicity of description, N=2.

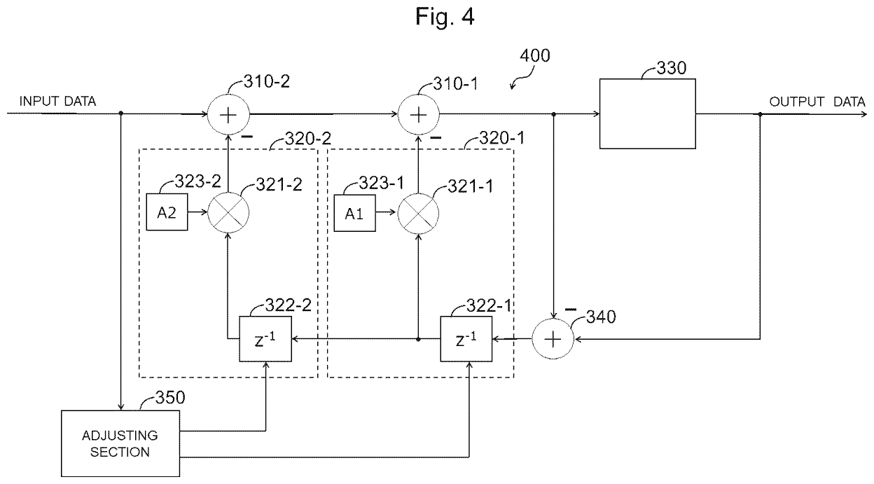

FIG. 4 is a diagram illustrating an example of a configuration of an error feedback delta-sigma modulation circuit 400. Regarding the delta-sigma modulation circuit 400, the same components as those of the delta-sigma modulation circuit 300 of FIG. 3 are denoted by the same reference signs to omit overlapping description.

The delta-sigma modulation circuit 400 includes an adjusting section 350 in addition to the components illustrated in FIG. 3. The adjusting section 350 initializes a value of the delay device 322-1 and a value of a delay device 322-2 when first data of a signal block is input as input data.

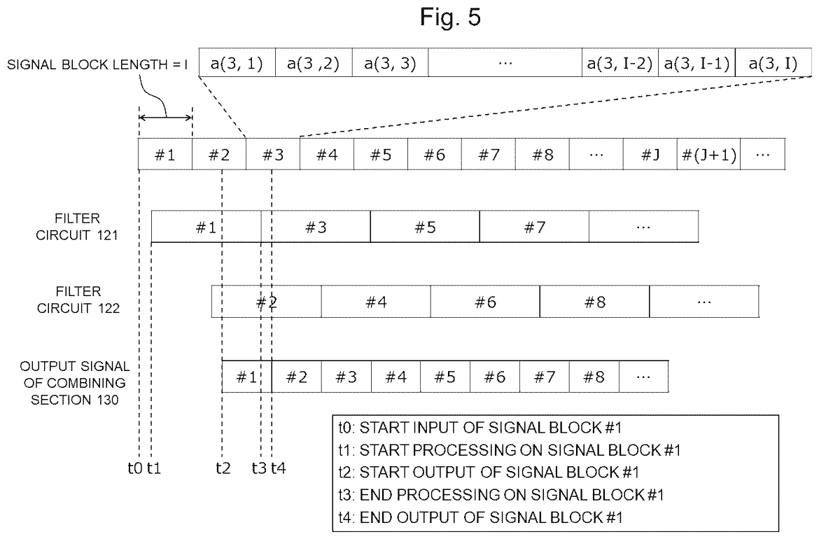

FIG. 5 is a diagram illustrating an example of a relationship between an input signal to the parallel circuit section 120 and an output signal from the combining section 130.

The first selection section 112 of the dividing section 110 divides digital data into a plurality of signal blocks. Here, the signal block has a predetermined data length “I”. In other words, the signal block includes I data segments (or data elements). Signal blocks with earliest input time are given identification numbers (signal block numbers) sequentially in descending order. A J-th (J is a natural number) signal block is expressed as “signal block #J”.

An x-th data segment of signal block #J is expressed as “a(J, x)”. When J or x has a smaller value, this means that a data segment given the value is a data segment input at an earlier time. When signal block #3 includes I data segments as described above, first data segment of signal block #3 is expressed as a(3, 1), and I-th (last) data segment is expressed as a(3, I).

The first selection section 112 alternately inputs the plurality of signal blocks to the filter circuits 121 and 122 sequentially from signal block #1 input at earliest time. For example, the first selection section 112 inputs certain signal block #J to the filter circuit 121, and inputs subsequent signal block #J+1 to the filter circuit 122. The first selection section 112 repeatedly performs such operation.

Through the above operation, the first selection section 112 distributes odd-numbered signal blocks to the filter circuit 121 in order of being input to the dividing section 110. The first selection section 112 distributes even-numbered signal blocks to the filter circuit 122 in order of being input to the dividing section 110.

The delta-sigma modulation circuit 121-1 of the filter circuit 121 processes I data segments (input data) included in the signal block in input order to output data corresponding to the signal block to the second storage section 131 of the combining section 130. The delta-sigma modulation circuit 122-1 of the filter circuit 122 processes I data segments (input data) included in the signal block in input order to output data corresponding to the signal block to the second storage section 131 of the combining section 130. Note that each of the delta-sigma modulation circuits 121-1 and 122-1 includes the configuration of FIG. 4. Immediately before the delta-sigma modulation circuit 121-1 processes the first data of each signal block, the adjusting section 350 sets the value of the delay device 322-1 and the value of the delay device 322-2 to initial values. As the initial values, for example, 0 is used. Similarly, immediately before the delta-sigma modulation circuit 122-1 processes the first data of each signal block, the adjusting section 350 sets the value of the delay device 322-1 and the value of the delay device 322-2 to the initial values.

Here, a value obtained by multiplying a time length of the signal block (=“the number of data segments included in the signal block”×“sampling time”) by the number of filter circuits (in the present example, 2) is referred to as “first time”. If the filter circuits 121 and 122 complete processing within the first time, the filter circuits 121 and 122 can perform processing in real time. In other words, if a drive frequency of a hardware circuit is greater than or equal to one over the number of filter circuits of a sampling frequency, the filter circuits 121 and 122 can perform processing in real time.

The second selection section 132 of the combining section 130 sequentially outputs data from data stored in the second storage section 131 at earliest time (i.e., data processed by the parallel circuit section 120 at earliest time).

For example, in the example of FIG. 5, at time t0, the first selection section 112 starts input of signal block #1 to the filter circuit 121. At time t1, the delta-sigma modulation circuit 121-1 of the filter circuit 121 starts processing on signal block #1. At time t2, the second selection section 132 of the combining section 130 starts output of processed results of signal block #1. Note that, in parallel with such processing, the delta-sigma modulation circuit 122-1 of the filter circuit 122 performs processing on signal block #2. At time t3, the delta-sigma modulation circuit 122-1 ends the processing on signal block #1. At time t4, the second selection section 132 ends output of the processed results of signal block #1. Subsequently, the second selection section 132 starts output of processed results of signal block #2.

According to the configuration described above, high-speed digital data can be processed with a hardware circuit having a drive frequency lower than a sampling frequency of the input signal.

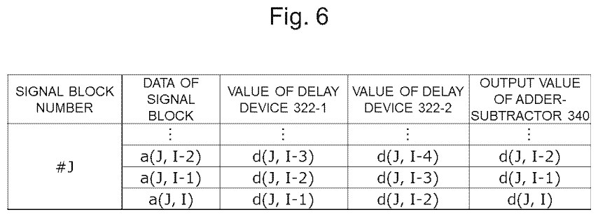

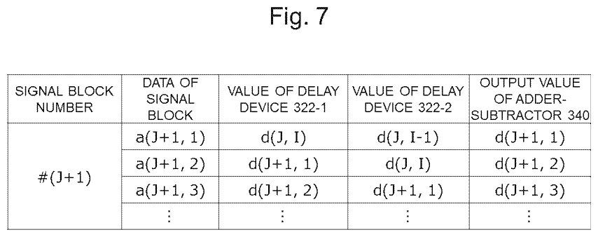

However, in the configuration, there is an issue in that a calculation error occurs near a boundary of continuous signal blocks. The delta-sigma modulation circuits 121-1 and 122-1 process temporally continuous signal blocks in parallel. For example, it is assumed that the delta-sigma modulation circuit 121-1 processes a preceding signal block and the delta-sigma modulation circuit 122-1 processes a subsequent signal block. In this case, the delta-sigma modulation circuit 121-1 cannot notify the delta-sigma modulation circuit 122-1 of a state (final state) at the time point of processing the last data of the signal block. The issue will be described with reference to FIG. 6 and FIG. 7.

Each row of each table of FIG. 6 and FIG. 7 may be referred to as a “circuit state” when data of the signal block is processed. Particularly, the circuit state with respect to the first data of the signal block may be referred to as an “initial state”. Furthermore, the circuit state with respect to the last data of the signal block may be referred to as a “final state”.

In the following, J is an odd number. It is assumed that the delta-sigma modulation circuit 121-1 processes preceding signal block #J and the delta-sigma modulation circuit 122-1 processes subsequent signal block #J+1.

FIG. 6 is a table illustrating the circuit state of the delta-sigma modulation circuit 121-1 in a process of processing signal block #J. Specifically, FIG. 6 illustrates combinations of the value of the delay device 322-1, the value of the delay device 322-2, and the output value (error signal) of the adder-subtractor 340 in the process of processing data from data a(J, I−2) to data a(J, I).

For example, in the row of data a(J, I−2), the value of the delay device 322-1 is d(J, I−3) and the value of the delay device 322-2 is d(J, I−4). d(J, I−3) corresponds to the output value of the adder-subtractor 340 when data a(J, I−3) is processed. d(J, I−4) corresponds to the output value of the adder-subtractor 340 when data a(J, I−4) is processed. Thus, when the data a(J, I−2) is processed, d(J, I−2) is obtained as the output value of the adder-subtractor 340, using the last output value d(J, I−3) of the adder-subtractor 340, the second to last output value d(J, I−4) of the adder-subtractor 340, and the data a(J, I−2). The same applies to other rows.

FIG. 7 is a table illustrating the circuit state of the delta-sigma modulation circuit 122-1 in a process of processing signal block #J+1. Specifically, FIG. 7 illustrates combinations of the value of the delay device 322-1, the value of the delay device 322-2, and the output value (error signal) of the adder-subtractor 340 in the process of processing data from data a(J+1, 1) to data a(J+1, 3).

Here, there is an issue in that the circuit state in the first row of the table of FIG. 7 cannot be implemented. This is due to the following reason. When the delta-sigma modulation circuit 122-1 processes the data a(J+1, 1), the delta-sigma modulation circuit 121-1 has not yet completed processing (for example, see FIG. 5). Specifically, the delta-sigma modulation circuit 121-1 has not yet completed processing on data a(J, I−1) and processing on data a(J, I). The delta-sigma modulation circuit 122-1 cannot receive a value (i.e., d(J, I)) to be stored in the delay device 322-1 and a value (i.e., d(J, I−1)) to be stored in the delay device 322-2 from the delta-sigma modulation circuit 121-1.

Thus, the delta-sigma modulation circuit 122-1 has no alternative but to process the data a(J+1, 1), using the initial values (for example, values having the highest probability) as the value of the delay device 322-1 and the value of the delay device 322-2.

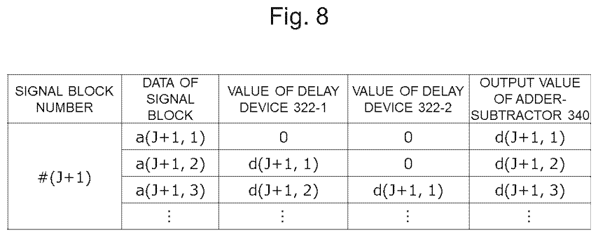

FIG. 8 is a table illustrating the circuit state of the delta-sigma modulation circuit 122-1 in a process of processing signal block #J+1, and illustrates an example in which the value of the delay device 322-1 and the value of the delay device 322-2 are set to the initial values. It is desirable that the initial values be values having the highest probability of occurrence out of the output values of the adder-subtractor 340; however, in the following, for the sake of simplicity, the initial values are assumed as 0. For example, immediately before the delta-sigma modulation circuit 122-1 processes the first data a(J+1, 1) of signal block #J+1, the adjusting section 350 sets the value of the delay device 322-1 and the value of the delay device 322-2 to the initial values (=0).

As described above, at the time of processing the first data a(J+1, 1) of signal block #J+1, the delta-sigma modulation circuit 122-1 cannot use the circuit state (i.e., the final state) when the last data a(J, I) of preceding signal block #J is processed. Thus, for example, the output value d(J+1, 1) of the adder-subtractor 340 in the table of FIG. 7 and the output value d(J+1, 1) of the adder-subtractor 340 in the table of FIG. 8 may be different bit sequences.

The output signal of the combining section 130 is caused to pass through an analog low-pass filter to remove quantization noise spreading on both sides of a signal spectrum. When such processing is performed in each of the patterns of FIG. 7 and FIG. 8 and these signals are compared, an error may occur near a boundary of signal blocks. Such an error is hereinafter referred to as a “calculation error due to discontinuity”.

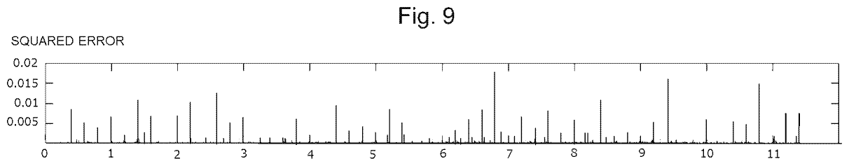

FIG. 9 is a graph illustrating an example of the calculation error due to discontinuity calculated by means of a simulation. The horizontal axis indicates time. The vertical axis is a squared error of a signal obtained by causing the output signal in the configuration including the delta-sigma modulation circuits arranged in parallel to pass through an analog low-pass filter and a signal obtained by causing the output signal in the configuration not including the delta-sigma modulation circuits arranged in parallel to pass through an analog low-pass filter. In calculation of FIG. 9, as the input signal, an OFDM signal having a signal bandwidth of 1 GHz and a sampling frequency of 12.5 GSps is used, and a data length of the signal block is 10,000.

In FIG. 9, an impulse squared error occurring with a period of 0.8 microseconds (=1/12.5 GSps×10,000) is the calculation error due to discontinuity. The magnitude of the calculation error due to discontinuity varies. This is due to the following reason. When the value of the delay device 322-1 and the output value of the adder-subtractor 340 in the final state of the delta-sigma modulation circuit in charge of processing of a preceding signal block are greatly different from the initial values (=0), a large squared error occurs, whereas when the values happen to be values close to the initial values, the squared error is small.

To address this, PTL 2 discloses a configuration of reducing the calculation error due to discontinuity. However, the configuration disclosed in PTL 2 has a plurality of conditional branches, and thus processing is complex. The configuration disclosed in PTL 2 is not suited for the plurality of delta-sigma modulation circuits arranged in parallel that are required to process a high-speed digital signal.

One or more example embodiments to be described below will provide a technology enabling reduction of the calculation error due to discontinuity with a simpler configuration than that in the related art (for example, PTL 2).

In order to solve the issue, the delta-sigma modulation apparatus according to one or more example embodiments includes a dividing section that divides an input signal into a plurality of blocks, two or more filter circuits arranged in parallel, and a combining section that combines a plurality of output signals corresponding to the plurality of blocks. Each of the two or more filter circuits includes two or more delta-sigma modulation circuits. Initial states of the two or more delta-sigma modulation circuits are different from each other. In other words, the two or more delta-sigma modulation circuits have different initial values. The two or more delta-sigma modulation circuits process the same signal block to output an output selection signal. The combining section selects an output signal of the delta-sigma modulation circuit having the initial state closest to the initial state of the delta-sigma modulation circuit that processes a subsequent signal block, the initial state being estimated from the final state of the delta-sigma modulation circuit that processes a preceding signal block.

### 1-2. Details of Example Embodiments

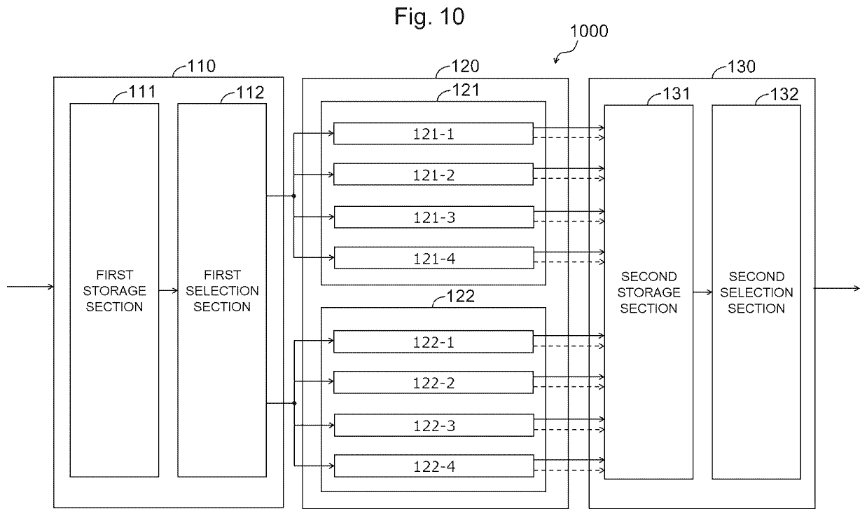

FIG. 10 is a diagram illustrating an example of a configuration of a delta-sigma modulation apparatus 1000. Regarding the delta-sigma modulation apparatus 1000, the same components as those of the delta-sigma modulation apparatus 10 are denoted by the same reference signs to omit overlapping description.

The parallel circuit section 120 includes a plurality of filter circuits 121 and 122. The plurality of filter circuits 121 and 122 are arranged in parallel. Note that, in the present example, for the sake of simplicity of description, the number of filter circuits is 2; however, the example embodiments are not restricted to this configuration. Three or more filter circuits may be arranged in parallel.

The filter circuit 121 includes a plurality of delta-sigma modulation circuits 121-1, . . . , 121-4. Similarly, the filter circuit 122 includes a plurality of delta-sigma modulation circuits 122-1, . . . , 122-4. In the present example, for the sake of description, although the filter circuit includes four delta-sigma modulation circuits, the filter circuit may include two or more delta-sigma modulation circuits.

The first selection section 112 inputs a plurality of signal blocks to the plurality of filter circuits 121 and 122. The plurality of filter circuits 121 and 122 output a plurality of output signals corresponding to the plurality of signal blocks. Here, the first selection section 112 inputs the same signal block to the plurality of delta-sigma modulation circuits 121-1, . . . , 121-4. Thus, the plurality of delta-sigma modulation circuits 121-1, . . . , 121-4 perform the delta-sigma modulation processing on the same signal block. Similarly, the first selection section 112 inputs the same signal block to the plurality of delta-sigma modulation circuits 122-1, . . . , 122-4. Thus, the plurality of delta-sigma modulation circuits 122-1, . . . , 122-4 perform the delta-sigma modulation processing on the same signal block.

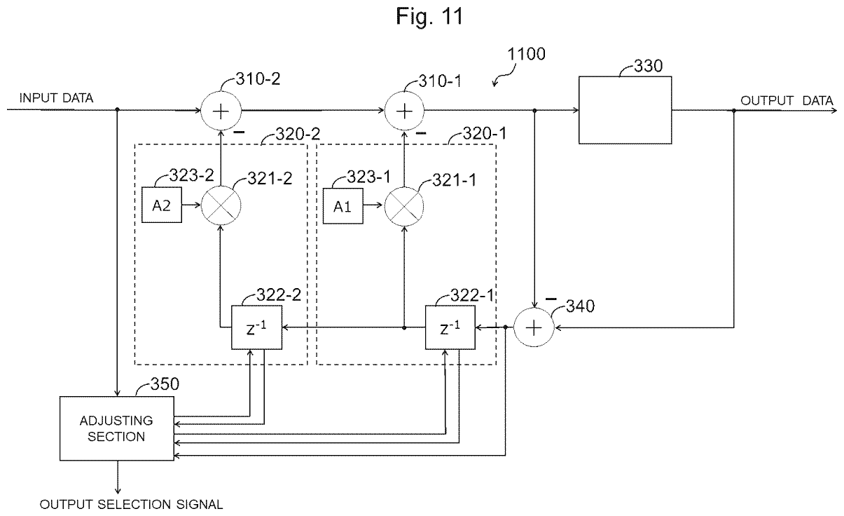

FIG. 11 is a diagram illustrating an example of a configuration of an error feedback delta-sigma modulation circuit 1100. The plurality of delta-sigma modulation circuits 121-1, . . . , 121-4 and the plurality of delta-sigma modulation circuits 122-1, . . . , 122-4 include the configuration of FIG. 11. Note that, regarding the delta-sigma modulation circuit 1100, the same components as those of the delta-sigma modulation circuit 400 of FIG. 4 are denoted by the same reference signs to omit overlapping description.

The adjusting section 350 refers to the output value of the adder-subtractor 340, the value of the delay device 322-1, and the value of the delay device 322-2. The adjusting section 350 outputs the output selection signal to the combining section 130. The output selection signal is used to combine the plurality of output signals corresponding to the plurality of signal blocks. The output selection signal may include at least one of the output value of the adder-subtractor 340, the value of the delay device 322-1, and the value of the delay device 322-2, for example.

In the following description, the delta-sigma modulation circuits 121-1 to 121-4 are collectively expressed as “delta-sigma modulation circuit(s) 121-n”, using an identification number n (n=1, 2, 3, 4) of the delta-sigma modulation circuits. The delta-sigma modulation circuits 122-1 to 122-4 are collectively expressed as “delta-sigma modulation circuit(s) 122-n”.

Similarly to the above, the first selection section 112 divides digital data into a plurality of signal blocks. The first selection section 112 alternately inputs the plurality of signal blocks to the filter circuits 121 and 122. For example, the first selection section 112 distributes odd-numbered signal blocks to the filter circuit 121. In other words, the first selection section 112 inputs odd-numbered signal blocks to each delta-sigma modulation circuit 121-n. The first selection section 112 distributes even-numbered signal blocks to the filter circuit 122. In other words, the first selection section 112 inputs even-numbered signal blocks to each delta-sigma modulation circuit 122-n.

Similarly to the above, it is assumed that the delta-sigma modulation circuits 121-n process the preceding signal block #J and the delta-sigma modulation circuits 122-n process the subsequent signal block #J+1.

Each of the delta-sigma modulation circuits 121-n performs delta-sigma modulation processing on the same signal block #J. Each of the delta-sigma modulation circuits 122-n performs delta-sigma modulation processing on the same signal block #J+1.

Here, the initial value of the delay device 322-1 and the initial value of the delay device 322-2 included in the delta-sigma modulation circuit 121-n are individually set. The initial value of the delay device 322-1 and the initial value of the delay device 322-2 included in the delta-sigma modulation circuit 122-n are individually set. Specifically, the initial value of the delay device 322-1 included in each of the delta-sigma modulation circuits 121-n and 122-n is expressed as “an”. The initial value of the delay device 322-2 included in each of the delta-sigma modulation circuits 121-n and 122-n is expressed as “βn”. As described above, n=1, 2, 3, 4.

The value of αn may be the output value of the adder-subtractor 340 when the last data a(J, I) of preceding signal block #J is processed. In consideration of this, for example, an information processing apparatus such as a computer may calculate distribution of the output values of the adder-subtractor 340 by means of a simulation or the like, and select a value having the highest probability of occurrence as the value of an based on the distribution in advance.

Similarly, the value of βn may be the value of the delay device 322-1 when the last data a(J, I) of preceding signal block #J is processed. In consideration of this, the information processing apparatus may calculate distribution of the values of the delay device 322-1 by means of a simulation or the like, and select a value having the highest probability of occurrence as the value of βn based on the distribution in advance.

For example, it is assumed that the probability that the output value of the adder-subtractor 340 has +0.5 and −0.5 is the highest and the probability that the value of the delay device 322-1 has +0.7 and −0.7 is the highest when the last data a(J, I) of signal block #J is processed. In this case, αn and βn may be set as follows. The following setting of αn and βn is hereinafter referred to as “setting 1”.
α1=+0.5
β1=+0.7
α2=+0.5
β2=−0.7
α3=−0.5
β3=+0.7
α4=−0.5
β4=−0.7

When there are a plurality of delta-sigma modulation circuits having the same combination of αn and βn, the delta-sigma modulation circuits have the same output signals, which makes the calculations useless. Thus, αn and βn may be set so that combinations of αn and βn are different from each other.

In the present example, when the adjusting section 350 processes the last data of a signal block to be processed, the adjusting section 350 outputs the output selection signal to the combining section 130. The output selection signal includes the output value of the adder-subtractor 340 when the last data of the signal block is processed and the value of the delay device 322-1 when the last data of the signal block is processed.

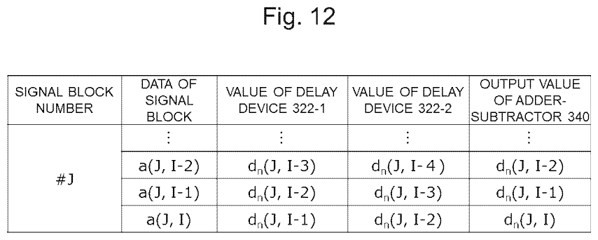

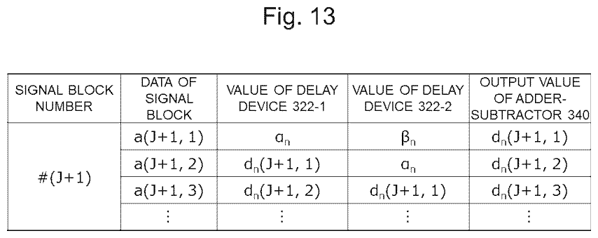

FIG. 12 is a table illustrating the circuit state of the delta-sigma modulation circuit 121-n in a process of processing signal block #J. FIG. 13 is a table illustrating the circuit state of the delta-sigma modulation circuit 122-n in a process of processing signal block #J+1.

The adjusting section 350 included in each of the delta-sigma modulation circuits 121-n outputs the value dn(J, I−1) of the delay device 322-1 and the output value dn(J, I) of the adder-subtractor 340 to the combining section 130 as the output selection signal at the time of processing the last data a(J, I) of signal block #J.

The adjusting section 350 included in each of the delta-sigma modulation circuits 122-n sets the value of the delay device 322-1 to αn and sets the value of the delay device 322-2 to βn at the time of processing the first data a(J+1, 1) of signal block #J+1. In a state in which the value of the delay device 322-1 and the value of the delay device 322-2 are set as described above, the delta-sigma modulation circuit 122-n performs delta-sigma modulation processing on the data a(J+1, 1).

The following will describe the combining processing in which the combining section 130 combines a plurality of output signals using the output selection signal.

Here, operation of the combining section 130 will be described based on the following assumption. The combining section 130 selects one of the delta-sigma modulation circuits 121-n to process preceding signal block #J. The delta-sigma modulation circuit selected as described above is referred to as a “first delta-sigma modulation circuit 121-s”. In the present example, the combining section 130 selects the delta-sigma modulation circuit 121-1 as the first delta-sigma modulation circuit 121-s.

Furthermore, the combining section 130 selects one of the delta-sigma modulation circuits 122-n to process subsequent signal block #J+1, using the output selection signal. The delta-sigma modulation circuit selected as described above is referred to as a “second delta-sigma modulation circuit 122-s”. The combining section 130 combines the output signal of the first delta-sigma modulation circuit 121-s and the output signal of the second delta-sigma modulation circuit 122-s.

Specifically, the second selection section 132 selects, as the second delta-sigma modulation circuit 122-s, the delta-sigma modulation circuit that has performed the delta-sigma modulation processing using a combination of αn and βn closest to the combination of the output value d1(J, I) of the adder-subtractor 340 and the value d1(J, I−1) of the delay device 322-1 included in the output selection signal received from the first delta-sigma modulation circuit 121-s (in the present example, the delta-sigma modulation circuit 121-1).

For example, it is assumed that αn and βn are set according to setting 1 above. Furthermore, it is assumed that the values included in the output selection signal received from the delta-sigma modulation circuit 121-1 are as follows.

Output value d1(J,I) of adder−subtractor 340=−0.9

Value d1(J,I−1) of delay device 322-1=+0.5

In this case, the combination of αn and βn closest to the combination of the output value d1(J, I) of the adder-subtractor 340 and the value d1(J, I−1) of the delay device 322-1 is a combination of α3 and β3. The second selection section 132 selects the delta-sigma modulation circuit 122-3 as the second delta-sigma modulation circuit 122-s. The second selection section 132 combines the output signal of the delta-sigma modulation circuit 121-1 and the output signal of the delta-sigma modulation circuit 122-3. For example, the second selection section 132 outputs the output signals in order of the signal block numbers. The second selection section 132 outputs the output signal of the delta-sigma modulation circuit 121-1 and then outputs the output signal of the delta-sigma modulation circuit 122-3.

The second selection section 132 may select the second delta-sigma modulation circuit 122-s, using the feedback gains A1 and A2. The second selection section 132 calculates the following expression (1) as the feedback amount.

$$A 1 \cdot d 1 ( J , I ) + A 2 \cdot d 1 ( J , I - 1 ) \qquad ( 1 )$$

Regarding αn and βn, the second selection section 132 calculates the following expression (2).

$$A 1 \cdot α n + A 2 \cdot β n \qquad ( 2 )$$

The second selection section 132 may select, as the second delta-sigma modulation circuit 122-s, the delta-sigma modulation circuit corresponding to the value of expression (2) closest to the value of expression (1).

For example, it is assumed that αn and βn are set according to setting 1 above. Furthermore, it is assumed that A1=+2.0 and A2=−1.0. Thus, the following holds.

$$A 1 \cdot d 1 ( J , I ) + A 2 \cdot d 1 ( J , I - 1 ) = - 2.3$$

$$A 1 \cdot α 1 + A 2 \cdot β1 = + 0.3$$

$$A 1 \cdot α2 + A 2 \cdot β2 = + 1.7$$

$$A 1 \cdot α3 + A 2 \cdot β3 = - 1.7$$

$$A 1 \cdot α 4 + A 2 \cdot β4 = - 0.3$$

The delta-sigma modulation circuit corresponding to the value of expression (2) closest to the value of expression (1) is the delta-sigma modulation circuit 122-3. Thus, the second selection section 132 selects the delta-sigma modulation circuit 122-3 as the second delta-sigma modulation circuit 122-s.

Note that, when the second selection section 132 selects the output signal of signal block #1, preceding signal block #0 is not present. In this case, the second selection section 132 may perform the above processing, on the assumption that d0(0, I)=0 and d0(0, I−1)=0.

According to the configuration described above, the delta-sigma modulation apparatus 1000 selects the delta-sigma modulation circuit that has performed processing using the initial state closest to the initial state (value of each delay device) estimated from the final state of the delta-sigma modulation circuit that has processed a preceding signal block out of the delta-sigma modulation circuits that have processed a subsequent signal block. Then, the delta-sigma modulation apparatus 1000 selects the output signal of the selected delta-sigma modulation circuit and performs the combining processing for combining a plurality of output signals. Thus, the calculation error due to discontinuity can be reduced.

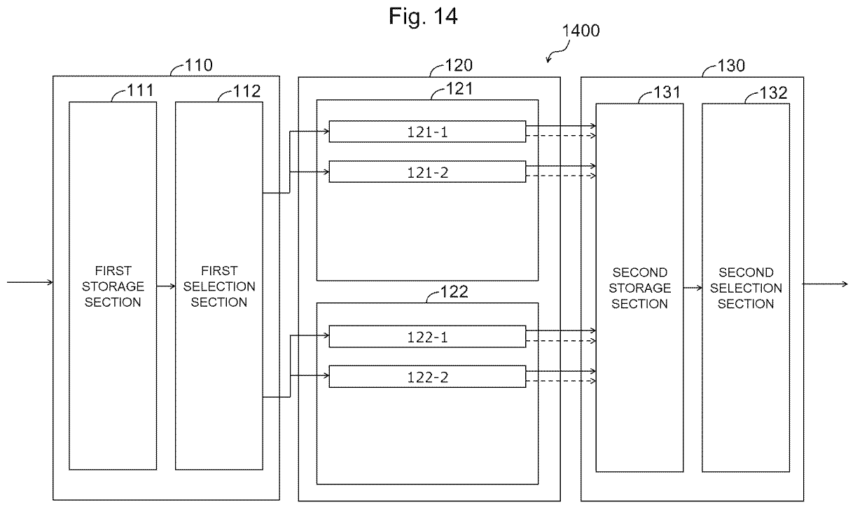

FIG. 14 is a diagram illustrating an example of a configuration of a delta-sigma modulation apparatus 1400. Regarding the delta-sigma modulation apparatus 1400, the same components as those of the delta-sigma modulation apparatus 1000 are denoted by the same reference signs to omit overlapping description.

In the delta-sigma modulation apparatus 1000, by increasing the number of delta-sigma modulation circuits included in each of the filter circuits 121 and 122, the number of combinations of αn and βn increases. This increases the probability of reducing a difference between the initial state of the delta-sigma modulation circuit 122-n that processes a subsequent signal block, the initial state being estimated from the final state of the delta-sigma modulation circuit 121-n that processes a preceding signal block, and an actual initial state of the delta-sigma modulation circuit 122-n that processes the subsequent signal block. This can enhance the effect of reducing the calculation error due to discontinuity. On the other hand, the circuit scale increases. To address this, the delta-sigma modulation apparatus 1400 includes a configuration enabling reduction of the circuit scale. Specifically, in the delta-sigma modulation apparatus 1400, the number of delta-sigma modulation circuits included in each of the filter circuits 121 and 122 is 2.

In the following description, the delta-sigma modulation circuits 121-1 to 121-2 are collectively expressed as “delta-sigma modulation circuit(s) 121-n”, using an identification number n (n=1, 2) of the delta-sigma modulation circuits. The delta-sigma modulation circuits 122-1 to 122-2 are collectively expressed as “delta-sigma modulation circuit(s) 122-n”.

Similarly to the above, the first selection section 112 divides digital data into a plurality of signal blocks. The first selection section 112 alternately inputs the plurality of signal blocks to the filter circuits 121 and 122. For example, the first selection section 112 distributes odd-numbered signal blocks to the filter circuit 121. In other words, the first selection section 112 inputs odd-numbered signal blocks to each delta-sigma modulation circuit 121-n. The first selection section 112 distributes even-numbered signal blocks to the filter circuit 122. In other words, the first selection section 112 inputs even-numbered signal blocks to each delta-sigma modulation circuit 122-n.

Similarly to the above, it is assumed that the delta-sigma modulation circuits 121-n process the preceding signal block #J and the delta-sigma modulation circuits 122-n process the subsequent signal block #J+1.

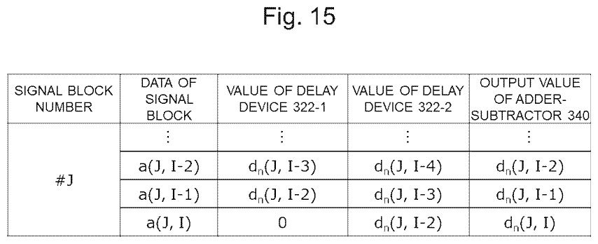

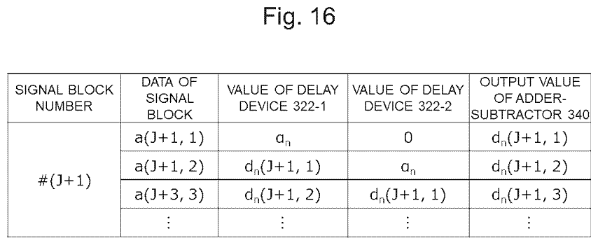

FIG. 15 is a table illustrating the circuit state of the delta-sigma modulation circuit 121-n in a process of processing signal block #J. FIG. 16 is a table illustrating the circuit state of the delta-sigma modulation circuit 122-n in a process of processing signal block #J+1.

As illustrated in FIG. 15, the delta-sigma modulation circuit 121-n replaces the value dn(J, I−1) of the delay device 322-1 with 0 at the time of processing the last data a (J, I) of signal block #J. In this state, the delta-sigma modulation circuit 121-n performs the delta-sigma modulation processing on the data a(J, I).

The adjusting section 350 included in each of the delta-sigma modulation circuits 121-n outputs the value dn(J, I−1) of the delay device 322-1 (i.e., the value before being substituted by 0) and the following expression (3) to the combining section 130 as the output selection signal.

$$dn ( J , I - 1 ) + dn ( J , I ) \qquad ( 3 )$$

As described above, the adjusting section 350 adjusts the feedback amount at the time of processing the last data of the signal block. Specifically, the adjusting section 350 sets the feedback amount of (N−1)-th order or lower to 0 at the time of processing the last data of the signal block. Furthermore, the adjusting section 350 outputs, as the output selection signal, the sum of a plurality of error signals calculated while processing data that precedes the last data of the signal block by N−1 to the last data. In the example, N=2. Thus, the adjusting section 350 sets the first-order feedback amount (i.e., the value of the delay device 322-1) to 0. The adjusting section 350 outputs, as the output selection signal, the sum of a plurality of error signals (i.e., expression (3)) calculated while processing data that precedes the last data of the signal block by 1 to the last data.

For example, when N=3, the adjusting section 350 may operate as follows. The adjusting section 350 sets the feedback amount of second order or lower (i.e., the value of the delay device 322-1 and the value of the delay device 322-2) to 0. The adjusting section 350 outputs, as the output selection signal, the sum of a plurality of error signals calculated while processing data that precedes the last data of the signal block by 2 to the last data.

As illustrated in FIG. 16, the delta-sigma modulation circuit 122-n sets an as the delay device (in the present example, the delay device 322-1) storing a value for calculating the first-order feedback amount and sets 0 as the delay device (in the present example, the delay device 322-2) for calculating the second-order feedback amount at the time of processing the first data a(J+1, 1) of signal block #J+1. In this state, the delta-sigma modulation circuit 122-n performs the delta-sigma modulation processing on the data a(J+1, 1).

As described above, the adjusting section 350 sets the feedback amount of second order or higher at the time of processing the first data of the signal block to 0. In the example, N=2. Thus, the adjusting section 350 sets only the second-order feedback amount (i.e., the value of the delay device 322-2) to 0.

The value of αn may be selected from the distribution of expression (3). The information processing apparatus may calculate distribution of the values of expression (3) by means of a simulation or the like, and select two values having the highest probability of occurrence as the value of αn based on the distribution in advance.

Here, it is assumed that the second selection section 132 of the combining section 130 selects the delta-sigma modulation circuit 121-1 as the first delta-sigma modulation circuit 121-s. Furthermore, the second selection section 132 selects the delta-sigma modulation circuit having the initial value an of the delay device 322-1 closest to the value of expression (3) as the second delta-sigma modulation circuit 122-s. The second selection section 132 combines the output signal of the first delta-sigma modulation circuit 121-s (i.e., the delta-sigma modulation circuit 121-1) and the output signal of the second delta-sigma modulation circuit 122-s.

Note that, in FIG. 15, it appears that the value of dn(J, I−1) does not pertain to the delta-sigma modulation processing and the output signal to be originally obtained is not output. However, the value of dn(J, I−1) pertains to the initial value an and the value of expression (3) included in the output selection signal, and thus the output signal with a reduced difference from the original output signal can be obtained.

According to the configuration described above, when the first data of the signal block is processed, the initial value of the delay device 322-2 is fixed to 0, and only the initial value of the delay device 322-1 is set to be different. This reduces the number of delta-sigma modulation circuits for implementing the delta-sigma modulation apparatus 1400, and as a result, the total circuit scale can be reduced. As described above, the configuration can reduce the calculation error due to discontinuity simultaneously with reducing the circuit scale.

As described above, the delta-sigma modulation apparatus 1400 replaces the initial value of the delay device 322-2 with 0 at the time of processing the first data of the signal block. Thus, the output value of the adder-subtractor 340 and the output signal of the delta-sigma modulation circuit are different in comparison to a case in which the initial value of the delay device 322-2 is not substituted by 0. This may cause a calculation error. Such a calculation error is hereinafter referred to as a “calculation error due to zero substitution”.

The following will describe an aspect of reducing the calculation error due to zero substitution. The configuration of the delta-sigma modulation apparatus is the same as the configuration in the one or more example embodiments, and thus overlapping description will be omitted.

Similarly to the above, the first selection section 112 divides digital data into a plurality of signal blocks. The first selection section 112 alternately inputs the plurality of signal blocks to the filter circuits 121 and 122. For example, the first selection section 112 distributes odd-numbered signal blocks to the filter circuit 121. In other words, the first selection section 112 inputs odd-numbered signal blocks to each delta-sigma modulation circuit 121-n. The first selection section 112 distributes even-numbered signal blocks to the filter circuit 122. In other words, the first selection section 112 inputs even-numbered signal blocks to each delta-sigma modulation circuit 122-n.

Similarly to the above, it is assumed that the delta-sigma modulation circuits 121-n process the preceding signal block #J and the delta-sigma modulation circuits 122-n process the subsequent signal block #J+1.

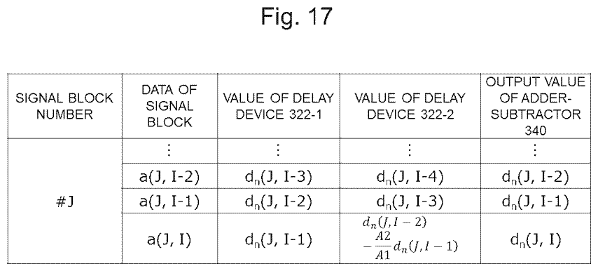

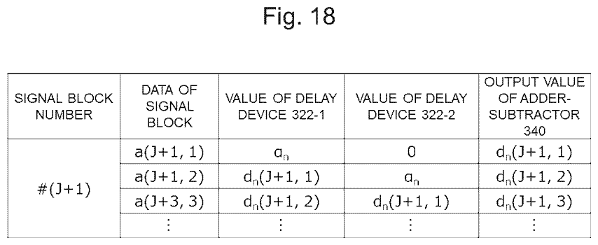

FIG. 17 is a table illustrating the circuit state of the delta-sigma modulation circuit 121-n in a process of processing signal block #J. FIG. 18 is a table illustrating the circuit state of the delta-sigma modulation circuit 122-n in a process of processing signal block #J+1.

As illustrated in FIG. 17, the delta-sigma modulation circuit 121-n substitutes the value of the following expression (4) for the value dn(J, I−2) of the delay device 322-2 at the time of processing the last data a(J, I) of signal block #J. The second term (right term) of expression (4) may be referred to as an “adjustment value for the value dn(J, I−2) of the delay device 322-2”.

$$\begin{matrix}[ Math . 1 ] & \\ {d}_{n} ( J , I - 2 ) - \frac{A 2}{A 1} {d}_{n} ( J , I - 1 ) & ( 4 )\end{matrix}$$

In a state in which the value dn(J, I−2) of the delay device 322-2 is substituted by the value of expression (4), the delta-sigma modulation circuit 121-n performs delta-sigma modulation processing on the data a(J, I).

The adjusting section 350 included in each of the delta-sigma modulation circuits 121-n outputs the value dn(J, I−1) of the delay device 322-1 and the following expression (5) calculated from the output value dn(I, J) of the adder-subtractor 340 to the combining section 130 as the output selection signal.

$$\begin{matrix}[ Math . 2 ] & \\ {d}_{n} ( J , I ) + \frac{A 2}{A 1} {d}_{n} ( J , I - 1 ) & ( 5 )\end{matrix}$$

As described above, the adjusting section 350 adjusts the feedback amount at the time of processing the last data of the signal block, using the adjustment value. The adjusting section 350 outputs the error signal at the time of processing the last data of the signal block and the adjustment value as the output selection signal. Specifically, the adjustment value is calculated based on one or more error signals calculated while processing data that precedes the last data of the signal block by N−1 to data that precedes the last data by 1. In the example, N=2. Thus, the adjustment value is calculated based on the error signal (i.e., dn(J, I−1)) calculated while processing the data that precedes the last data by 1. The adjustment value is a value obtained by multiplying dn(J, I−1) by a predetermined coefficient. As described above, the predetermined coefficient may be a value based on the feedback gains A1 and A2 (for example, expression (5)). The adjusting section 350 outputs the value dn(J, I−1) of the delay device 322-1 and the value of expression (5) as the output selection signal.

For example, when N=3, the adjustment value is calculated based on two error signals (i.e., dn(J, I−1) and dn(J, I−2)) calculated while processing data that precedes the last data of the signal block by 2 to data that precedes the last data by 1. The adjustment value may be a value obtained by multiplying each of dn(J, I−1) and dn(J, I−2) by a predetermined coefficient. As described above, the predetermined coefficient may be a value based on at least one of the feedback gains.

As illustrated in FIG. 18, the delta-sigma modulation circuit 122-n sets the delay device 322-1 to αn and sets the delay device 322-2 to 0 at the time of processing the first data a(J+1, 1) of signal block #J+1. In this state, the delta-sigma modulation circuit 122-n performs the delta-sigma modulation processing on the data a(J+1, 1).

The value of αn may be selected from the distribution of expression (5). The information processing apparatus may calculate distribution of the values of expression (5) by means of a simulation or the like, and select two values having the highest probability of occurrence as the value of αn based on the distribution in advance.

Here, it is assumed that the second selection section 132 of the combining section 130 selects the delta-sigma modulation circuit 121-1 as the first delta-sigma modulation circuit 121-s. Furthermore, the second selection section 132 selects the delta-sigma modulation circuit having the initial value an of the delay device 322-1 closest to the value of expression (5) as the second delta-sigma modulation circuit 122-s. The second selection section 132 combines the output signal of the first delta-sigma modulation circuit 121-s (i.e., the delta-sigma modulation circuit 121-1) and the output signal of the second delta-sigma modulation circuit 122-s.

According to the configuration described above, when the first data of the signal block is processed, the initial value of the delay device 322-2 is fixed to 0, and only the initial value of the delay device 322-1 is set to be different. This reduces the number of delta-sigma modulation circuits for implementing the delta-sigma modulation apparatus, and as a result, the total circuit scale can be reduced. Furthermore, when the last data of the signal block is processed, the value of the delay device 322-2 is not substituted by 0, and thus the calculation error due to zero substitution can be reduced.

Description will be provided for the calculation error when the value of the delay device 322-2 is substituted by the value of expression (4) when the last data a(J, I) of signal block #J is processed. The feedback amount using the second term (right term) of expression (4) is represented by the following expression (6).

$$\begin{matrix}[ Math . 3 ] & \\ - \frac{A {2}^{2}}{A 1} {d}_{n} ( J , I - 1 ) & ( 6 )\end{matrix}$$

The feedback amount using the value dn(J, I−1) of the delay device 322-1 is represented by the following expression (7).

$$\begin{matrix}[ Math . 4 ] & \\ A 1 {d}_{n} ( J , I - 1 ) & ( 7 )\end{matrix}$$

The sum of expression (6) and expression (7) is represented by the following expression (8).

$$\begin{matrix}[ Math . 5 ] & \\ A 1 ( 1 - {( \frac{A 2}{A 1} )}^{2} ) {d}_{n} ( J , I - 1 ) & ( 8 )\end{matrix}$$

In general, because (A2/A1)<1, it can be understood that influence can be reduced in comparison to a case in which the original feedback amount (i.e., expression (7)) equals 0 due to the zero substitution processing of the delay device 322-1. For example, when A1=+2 and A2=−1, 1−(A2/A1)²=0.75. Thus, errors in the first-order feedback amount at the time of processing the last data of the signal block can be reduced from 100% to 25%. According to the configuration, the calculation error due to zero substitution can be reduced, and the calculation error due to discontinuity can be reduced.

The feedback amount at the time of processing the last data a(J, I) of signal block #J is represented by the following expression (9).

$$\begin{matrix}[ Math . 6 ] & \\ A 1 {d}_{n} ( J , I - 1 ) + A 2 ( {d}_{n} ( J , I - 2 ) - \frac{A 2}{A 1} {d}_{n} ( J , I - 1 ) ) = A 1 ( 1 - {( \frac{A 2}{A 1} )}^{2} ) {d}_{n} ( J , I - 1 ) + A 2 {d}_{n} ( J , I - 2 ) & ( 9 )\end{matrix}$$

Thus, at the time of processing the last data a(J, I) of signal block #J, the adjusting section 350 may set the value of the delay device 322-1 to dn(J, I−1), set the value of the delay device 322-2 to dn(J, I−2), and set the feedback gain A1 of the coefficient storage 323-1 to the value of the following expression (10). With this configuration as well, the calculation error due to zero substitution can be reduced.

$$\begin{matrix}\{ Math . 7 ] & \\ A 1 ( 1 - {( \frac{A 2}{A 1} )}^{2} ) & ( 10 )\end{matrix}$$

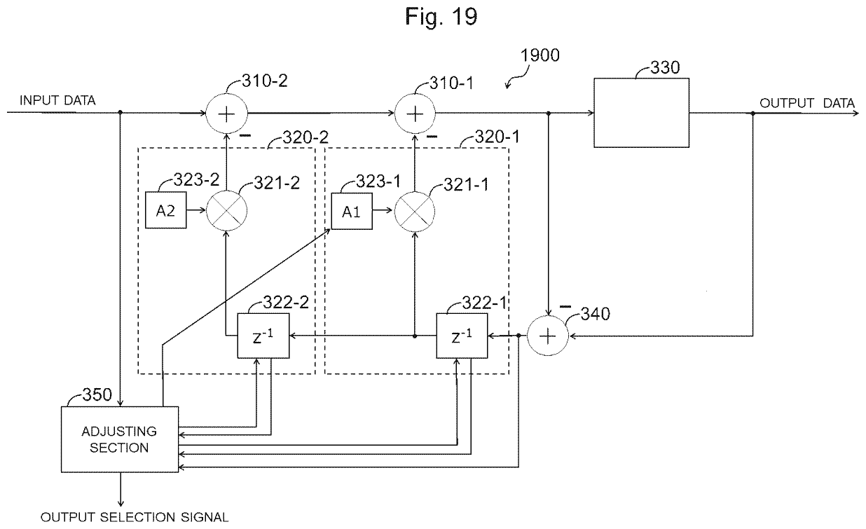

FIG. 19 is a diagram illustrating an example of a configuration of an error feedback delta-sigma modulation circuit 1900. In the delta-sigma modulation circuit 1900, the same components as those of the delta-sigma modulation circuit 1100 of FIG. 11 are denoted by the same reference signs to omit overlapping description.

In FIG. 19, a path from the adjusting section 350 to the coefficient storage 323-1 is added. For example, the adjusting section 350 can substitute the value of expression (10) for the feedback gain A1 of the coefficient storage 323-1 at the time of processing the last data a(J, I) of signal block #J.

According to the configuration, when the value of expression (10) is known, the adjusting section 350 can set the feedback gain A1 of the coefficient storage 323-1 to the value of expression (10) in advance. In the configuration, the value to be set to the delay device 322-2 (i.e., the value of expression (4)) need not be calculated for each signal block. Thus, the circuit scale can be further reduced.

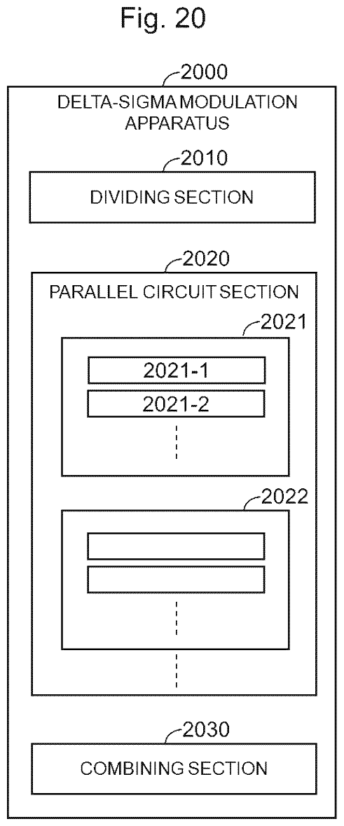

In the following, a more generalized example embodiment will be described. FIG. 20 is a diagram illustrating an example of a configuration of a delta-sigma modulation apparatus 2000. The delta-sigma modulation apparatus 2000 includes a dividing section 2010, a parallel circuit section 2020, and a combining section 2030.

The dividing section 2010 divides an input signal into a plurality of signal blocks, and inputs the plurality of signal blocks to the parallel circuit section 2020.

The parallel circuit section 2020 includes two or more filter circuits 2021 and 2022 arranged in parallel. The two or more filter circuits 2021 and 2022 perform delta-sigma modulation processing on the plurality of signal blocks to output a plurality of output signals corresponding to the plurality of signal blocks. Each of the two or more filter circuits 2021 and 2022 includes two or more delta-sigma modulation circuits including different initial values. For example, the filter circuit 2021 includes two or more delta-sigma modulation circuits 2021-1 and 2021-2.

The combining section 2030 performs combining processing for combining the plurality of output signals.

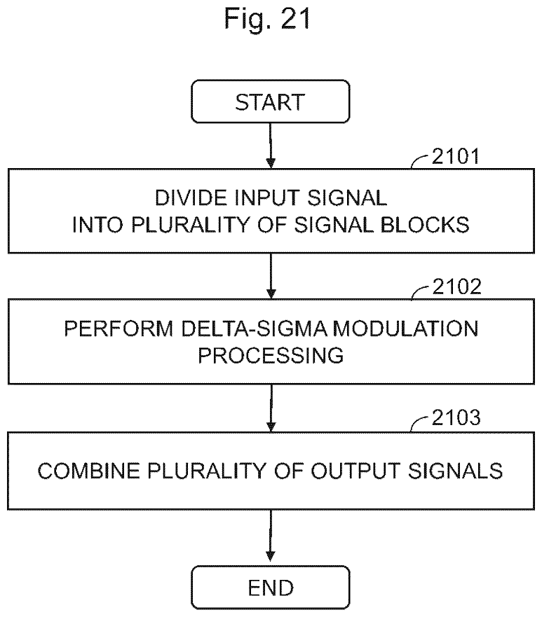

FIG. 21 is a flowchart for illustrating an example of a flow of processing of the delta-sigma modulation apparatus 2000.

The dividing section 2010 divides an input signal into a plurality of signal blocks (2101). The dividing section 2010 inputs the plurality of signal blocks to the two or more filter circuits 2021 and 2022.

The parallel circuit section 2020 performs delta-sigma modulation processing (2102). Specifically, the two or more delta-sigma modulation circuits perform delta-sigma modulation processing on the same signal block to output one of the output signals to the combining section 2030 and output an output selection signal for combining the plurality of output signals to the combining section 2030.

The combining section 2030 performs combining processing for combining the plurality of output signals output from the parallel circuit section 2020 (2103). Specifically, the combining section 2030 performs the combining processing, using the output selection signal of the delta-sigma modulation circuit that processes a preceding signal block among the plurality of signal blocks and initial values.

According to the configuration, the calculation error due to discontinuity can be reduced. Note that the dividing section 2010 may have a configuration similar to that of the dividing section 110. The parallel circuit section 2020 may have a configuration similar to that of the parallel circuit section 120. The combining section 2030 may have a configuration similar to that of the combining section 130.

### 1-3. Configuration of Hardware

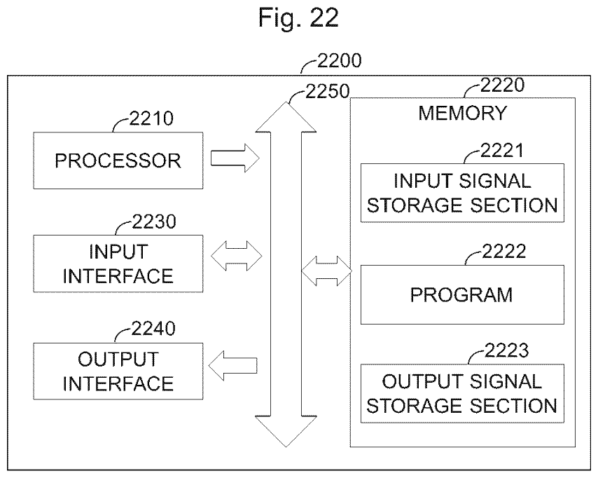

FIG. 22 is a diagram illustrating an example of an information processing apparatus 2200 for implementing the delta-sigma modulation apparatus.

The information processing apparatus 2200 includes a processor 2210, a memory 2220, an input interface 2230, and an output interface 2240. The processor 2210, the memory 2220, the input interface 2230, and the output interface 2240 are connected to each other via a bus 2250.

The processor 2210 may include one or more of a central processing unit (CPU), a micro processing unit (MPU), and a micro controller, for example. The processor 2210 executes a program 2222 stored in the memory 2220 and thereby implements the delta-sigma modulation apparatus according to the one or more example embodiments.

The memory 2220 is an element that temporarily or permanently stores the program (instructions) 2222 and data used to perform various types of processing in the delta-sigma modulation apparatus. The memory 2220 includes a volatile memory and a non-volatile memory. The volatile memory may include a random access memory (RAM), for example. The non-volatile memory may include one or more of a read only memory (ROM), a hard disk drive (HDD), and a solid state drive (SSD), for example. The memory 2220 includes an input signal storage section 2221 for temporarily storing input signals and an output signal storage section 2223 for temporarily storing output signals.

The input interface 2230 is an interface for receiving an input from a user or another information processing apparatus. The output interface 2240 is an interface for performing an output to a display section (not illustrated) or another information processing apparatus.

### 2. OTHER EXAMPLE EMBODIMENTS

Descriptions have been given above of the example embodiments of the present disclosure; however, the present disclosure is not limited to these example embodiments. It should be understood by those of ordinary skill in the art that these example embodiments are merely examples and that various alterations are possible without departing from the scope and the spirit of the present disclosure.

For example, the steps in the processing described in the Specification may not necessarily be executed in time series in the order described in the corresponding sequence diagram. For example, the steps in the processing may be executed in an order different from that described in the corresponding sequence diagram or may be executed in parallel. Some of the steps in the processing may be deleted, or more steps may be added to the processing.

Moreover, methods including processing of the constituent elements may be provided, and programs for causing a processor to execute processing of the constituent elements may be provided. Moreover, non-transitory computer readable recording media (non-transitory computer readable media) having recorded thereon the programs may be provided. It is apparent that such apparatuses, modules, methods, programs, and non-transitory computer readable recording media are also included in the present disclosure.

The whole or part of the example embodiments disclosed above can be described as, but not limited to, the following supplementary notes.

### Supplementary Note 1

A delta-sigma modulation apparatus comprising:
one or more memories storing instructions; and
one or more processors configured to execute the instructions to
   divide an input signal into a plurality of signal blocks;
   implement a parallel circuit including two or more filter circuits arranged in parallel and configured to perform delta-sigma modulation processing on the plurality of signal blocks to output a plurality of output signals corresponding to the plurality of signal blocks, each of the two or more filter circuits including two or more delta-sigma modulation circuits including different initial values; and
   perform combining processing for combining the plurality of output signals,
wherein the two or more delta-sigma modulation circuits in each of the two or more filter circuits are configured to perform the delta-sigma modulation processing on a same signal block to output one of the plurality of output signals and output an output selection signal for combining the plurality of output signals, and
the one or more processors are further configured to execute the instructions to perform the combining processing using the initial values and the output selection signal from one of the two or more delta-sigma modulation circuits that processes a preceding signal block among the plurality of signal blocks.

### Supplementary Note 2

The delta-sigma modulation apparatus according to supplementary note 1, wherein
the one or more processors are further configured to execute the instructions to, in the combining processing,
   select one of the two or more delta-sigma modulation circuits that processes the preceding signal block as a first delta-sigma modulation circuit,
   select one of the two or more delta-sigma modulation circuits that processes a subsequent signal block following the preceding signal block as a second delta-sigma modulation circuit, and
   combine the output signal of the first delta-sigma modulation circuit and the output signal of the second delta-sigma modulation circuit.

### Supplementary Note 3

The delta-sigma modulation apparatus according to supplementary note 2, wherein
the output selection signal includes an error signal when the first delta-sigma modulation circuit processes last data of the preceding signal block and a value of a delay device when the first delta-sigma modulation circuit processes the last data of the preceding signal block, and
the one or more processors are further configured to execute the instructions to select one of the two or more delta-sigma modulation circuits having an initial value closest to the output selection signal out of the two or more delta-sigma modulation circuits that process the subsequent signal block as the second delta-sigma modulation circuit.

### Supplementary Note 4

The delta-sigma modulation apparatus according to supplementary note 2, wherein
the delta-sigma modulation circuit is an N-th-order (N≥2) delta-sigma modulation circuit, and
the one or more processors are further configured to execute the instructions to perform adjusting processing to set a feedback amount of second order or higher when one of the two or more delta-sigma modulation circuits processes first data of one of the plurality of signal blocks to 0, and adjust the feedback amount when the one of the two or more delta-sigma modulation circuits processes last data of the one of the plurality of signal blocks.

### Supplementary Note 5

The delta-sigma modulation apparatus according to supplementary note 4, wherein
the one or more processors are further configured to execute the instructions to, in the adjusting processing, set the feedback amount of (N−1)-th order or lower to 0 at time of processing the last data of the one of the plurality of signal blocks, and
the one or more processors are further configured to execute the instructions to, in the adjusting processing, output a sum of a plurality of error signals calculated while processing data that precedes the last data of the one of the plurality of signal blocks by N−1 to the last data, as the output selection signal.

### Supplementary Note 6

The delta-sigma modulation apparatus according to supplementary note 4, wherein
the one or more processors are further configured to execute the instructions to, in the adjusting processing, adjust the feedback amount at time of processing the last data of the one of the plurality of signal blocks, using an adjustment value,
the adjustment value is calculated based on one or more error signals calculated while processing data that precedes the last data of the one of the plurality of signal blocks by N−1 to data that precedes the last data by 1, and
the one or more processors are further configured to execute the instructions to, in the adjusting processing, output the one or more error signals at time of processing the last data of the one of the plurality of signal blocks and the adjustment value, as the output selection signal.

### Supplementary Note 7

The delta-sigma modulation apparatus according to supplementary note 4, wherein
the one or more processors are further configured to execute the instructions to, in the adjusting processing,
   change a feedback gain at time of processing the last data of the one of the plurality of signal blocks to a predetermined value, and
      output an error signal at time of processing the last data of the one of the plurality of signal blocks and an adjustment value for the error signal, as the output selection signal, and
   the adjustment value is calculated based on one or more of the error signals calculated while processing data that precedes the last data of the one of the plurality of signal blocks by N−1 to data that precedes the last data by 1.

### Supplementary Note 8

A delta-sigma modulation method comprising:
dividing an input signal into a plurality of signal blocks;
inputting the plurality of signal blocks to two or more filter circuits to output a plurality of output signals corresponding to the plurality of signal blocks, the two or more filter circuits being arranged in parallel, each of the two or more filter circuits including two or more delta-sigma modulation circuits including different initial values; and
performing combining processing for combining the plurality of output signals, wherein
the delta-sigma modulation method further comprises:
performing delta-sigma modulation processing on a same signal block to output one of the plurality of output signals and an output selection signal for combining the plurality of output signals, using the two or more delta-sigma modulation circuits in each of the two or more filter circuits; and
performing the combining processing using the initial values and the output selection signal from one of the two or more delta-sigma modulation circuits that processes a preceding signal block among the plurality of signal blocks.

What is claimed is:

1. A delta-sigma modulation apparatus comprising:
one or more memories storing instructions; and
one or more processors configured to execute the instructions to divide an input signal into a plurality of signal blocks;
implement a parallel circuit including two or more filter circuits arranged in parallel and configured to perform delta-sigma modulation processing on the plurality of signal blocks to output a plurality of output signals corresponding to the plurality of signal blocks, each of the two or more filter circuits including two or more delta-sigma modulation circuits including different initial values; and
perform combining processing for combining the plurality of output signals,
wherein the two or more delta-sigma modulation circuits in each of the two or more filter circuits are configured to perform the delta-sigma modulation processing on a same signal block to output one of the plurality of output signals and output an output selection signal for combining the plurality of output signals, and
the one or more processors are further configured to execute the instructions to perform the combining processing using the initial values and the output selection signal from one of the two or more delta-sigma modulation circuits that processes a preceding signal block among the plurality of signal blocks.

2. The delta-sigma modulation apparatus according to claim 1, wherein
the one or more processors are further configured to execute the instructions to, in the combining processing,
select one of the two or more delta-sigma modulation circuits that processes the preceding signal block as a first delta-sigma modulation circuit,
select one of the two or more delta-sigma modulation circuits that processes a subsequent signal block following the preceding signal block as a second delta-sigma modulation circuit, and
combine the output signal of the first delta-sigma modulation circuit and the output signal of the second delta-sigma modulation circuit.

3. The delta-sigma modulation apparatus according to claim 2, wherein
the output selection signal includes an error signal when the first delta-sigma modulation circuit processes last data of the preceding signal block and a value of a delay device when the first delta-sigma modulation circuit processes the last data of the preceding signal block, and
the one or more processors are further configured to execute the instructions to select one of the two or more delta-sigma modulation circuits having an initial value closest to the output selection signal out of the two or more delta-sigma modulation circuits that process the subsequent signal block as the second delta-sigma modulation circuit.

4. The delta-sigma modulation apparatus according to claim 2, wherein
the delta-sigma modulation circuit is an N-th-order (N≥2) delta-sigma modulation circuit, and
the one or more processors are further configured to execute the instructions to perform adjusting processing to set a feedback amount of second order or higher when one of the two or more delta-sigma modulation circuits processes first data of one of the plurality of signal blocks to 0, and adjust the feedback amount when the one of the two or more delta-sigma modulation circuits processes last data of the one of the plurality of signal blocks.

5. The delta-sigma modulation apparatus according to claim 4, wherein
the one or more processors are further configured to execute the instructions to, in the adjusting processing, set the feedback amount of (N−1)-th order or lower to 0 at time of processing the last data of the one of the plurality of signal blocks, and
the one or more processors are further configured to execute the instructions to, in the adjusting processing, output a sum of a plurality of error signals calculated while processing data that precedes the last data of the one of the plurality of signal blocks by N−1 to the last data, as the output selection signal.

6. The delta-sigma modulation apparatus according to claim 4, wherein
the one or more processors are further configured to execute the instructions to, in the adjusting processing, adjust the feedback amount at time of processing the last data of the one of the plurality of signal blocks, using an adjustment value,
the adjustment value is calculated based on one or more error signals calculated while processing data that precedes the last data of the one of the plurality of signal blocks by N−1 to data that precedes the last data by 1, and
the one or more processors are further configured to execute the instructions to, in the adjusting processing, output the one or more error signals at time of processing the last data of the one of the plurality of signal blocks and the adjustment value, as the output selection signal.

7. The delta-sigma modulation apparatus according to claim 4, wherein
the one or more processors are further configured to execute the instructions to, in the adjusting processing,
change a feedback gain at time of processing the last data of the one of the plurality of signal blocks to a predetermined value, and
output an error signal at time of processing the last data of the one of the plurality of signal blocks and an adjustment value for the error signal, as the output selection signal, and
the adjustment value is calculated based on one or more of the error signals calculated while processing data that precedes the last data of the one of the plurality of signal blocks by N−1 to data that precedes the last data by 1.

8. A delta-sigma modulation method comprising:
dividing an input signal into a plurality of signal blocks;
inputting the plurality of signal blocks to two or more filter circuits to output a plurality of output signals corresponding to the plurality of signal blocks, the two or more filter circuits being arranged in parallel, each of the two or more filter circuits including two or more delta-sigma modulation circuits including different initial values; and
performing combining processing for combining the plurality of output signals, wherein
the delta-sigma modulation method further comprises:
performing delta-sigma modulation processing on a same signal block to output one of the plurality of output signals and an output selection signal for combining the plurality of output signals, using the two or more delta-sigma modulation circuits in each of the two or more filter circuits; and
performing the combining processing using the initial values and the output selection signal from one of the two or more delta-sigma modulation circuits that processes a preceding signal block among the plurality of signal blocks.
